(19) United States
(12) Patent Application Publication
(10) Pub. No.: US 2018/0259576 A1
(43) Pub. Date: Sep. 13, 2018

(54) IMPLEMENTING INTEGRATED CIRCUIT YIELD ENHANCEMENT THROUGH ARRAY FAULT DETECTION AND CORRECTION USING COMBINED ABIST, LBIST, AND REPAIR TECHNIQUES

(71) Applicant: International Business Machines Corporation, Armonk, NY (US)

(72) Inventors: Steven M. Douskey, Rochester, MN (US); Michael J. Hamilton, Rochester, MN (US); Amanda R. Kaufer, Rochester, MN (US); Phillip A. Senum, Rochester, MN (US)

(21) Appl. No.: 15/454,338

(22) Filed: Mar. 9, 2017

(51) Int. Cl. G01R 31/3187; G01R 31/3177; G01R 31/317

(52) U.S. Cl. CPC G01R 31/3187; G01R 31/31724; G01R 31/3177

(57) ABSTRACT

A method and system are provided for implementing integrated circuit yield enhancement through array fault detection and correction using combined Logic Built in Self Test (LBIST) diagnostics, and Array Built in Self-Test (ABIST) repair techniques to identify failures in the random logic feeding to and from array and array cell fails. The combination of running LBIST along with the arrays while also implementing a method of recording the array related LBIST fails for inclusion into a repair algorithm using the redundant array structures enables integrated circuit yield enhancement.

### FIELD OF THE INVENTION

The present invention relates generally to the data processing field, and more particularly, relates to a method and circuit for implementing integrated circuit yield enhancement through array fault detection and correction using combined Array Built in Self-Test (ABIST) and Logic Built in Self Test (LBIST) diagnostics, and repair techniques, methods and algorithms, and a design structure on which the subject circuit resides.

### DESCRIPTION OF THE RELATED ART

Array Built In Self-Test (ABIST) and Logic Built In Self-Test (LBIST) are both well-known methods for testing integrated circuits. Both methods provide at speed, on chip test coverage of their respective portions of logic; ABIST for arrays, with most of the remaining random chip logic using LBIST. There is however an interface and area of logic that is not activated by either test individually, as LBIST normally runs with the arrays in a special write-through mode of operation which bypasses the arrays, while array test only tests the array cells themselves. The actual functional path usage of the arrays are normally a super-set of the paths tested using ABIST and LBIST separately.

Running LBIST while including the arrays using their normal functional path provides additional coverage of the interface between logic and arrays and more closely resembles the actual system functional operation of the device. This combined mode of LBIST operation has been demonstrated by progressive and thorough implementations of LBIST and ABIST logic for the purpose of increased fault coverage.

A need exists for an effective and efficient mechanism for implementing further enhancements and usage of the resultant data from a combined ABIST and LBIST testing to effectuate greater chip yield. It is desirable to recover yield loss due to bad array cells in both manufacturing and field environments.

### SUMMARY OF THE INVENTION

Principal aspects of the present invention are to provide a method and system for implementing integrated circuit yield enhancement through array fault detection and correction using combined Array Built in Self-Test (ABIST) and Logic Built in Self Test (LBIST) diagnostics, and repair techniques. Other important aspects of the present invention are to provide such method and system substantially without negative effects that overcome many of the disadvantages of prior art arrangements.

In brief, a method and system are provided for implementing integrated circuit yield enhancement through array fault detection and correction using combined ABIST and LBIST diagnostics, and repair techniques. A combined operation of LBIST and ABIST logic is used to identify failures in the random logic feeding to and from array and array cell fails. The combination of running LBIST along with the arrays while also implementing a method of recording the array related LBIST fails for inclusion into a repair algorithm using the redundant array structures enables integrated circuit yield enhancement.

In accordance with features of the invention, the combined run advantageously identifies unique array failures in both the array and the interface logic providing increased fault coverage.

In accordance with features of the invention, by running the combined LBIST and repair algorithm after device incorporation into a system, and also in delivered systems helps alleviate early life array fails.

In accordance with features of the invention, the running LBIST along with the arrays while also implementing a method of recording the array related LBIST fails for inclusion into a repair algorithm includes noting and recording Multiple Input Signature Register (MISR) data.

In accordance with features of the invention, to diagnose failing data optionally includes reducing full test to first single failing cycle of implicated MISR, reducing MISR cycle data to single failing channel, and reducing the channel to single failing bit information.

In accordance with features of the invention, the combined LBIST includes mapping failing bit data into a repair register with unique use of fail data to repair array cell. Failing bit can be mapped to a failing address repair register (FARR). Failing bit is now known, and can be mapped to redundant cell using offline tables and manual intervention. Once the data is mapped, the repair information becomes a resident part of array repair.

In accordance with features of the invention, array repair is performed with updated repair information. Then re-running combined LBIST is performed to assure the repair is correct and complete.

In accordance with features of the invention, in the case of multiple core logic comparing a passing region directly to a failing region can immediately identify the implicated array cell locations. In a case of several identical cores, the post combined LBIST run answers between each core can be directly compared to produce a majority answer and direct comparison of dissenting bits can be recognized and used for mapping repair bits.

In accordance with features of the invention, diagnosing failing data is based on MISR pass/fail results. In the case of a passing MISR, no action is required. One or more failing MISRs indicates analysis and possible repair is needed.

In accordance with features of the invention, the combined operation of LBIST and ABIST logic includes capturing fails in sticky bits, a repair operation initiated using sticky bit data, recorded on chip, subsequently mapped to repairs.

In accordance with features of the invention, after repairing arrays, re-running combined LBIST is performed, and fails are recorded using redundant writes and voting.

In accordance with features of the invention, by employing parts of the ABIST logic and repair facilities, during LBIST operation; unique array cell fails are captured and added to the chips redundant cell solution, when the unique array cell fails would otherwise be counted as yield loss.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1 and 2A together provide a schematic and block diagram representation illustrating an exemplary computer test system and circuit for implementing integrated circuit yield enhancement through array fault detection and correction using combined Logic Built in Self Test (LBIST) diagnostics, and Array Built in Self-Test (ABIST) repair techniques in accordance with preferred embodiments;

FIGS. 2B illustrates example operational steps for implementing integrated circuit yield enhancement through array fault detection and correction using combined Logic Built in Self Test (LBIST) diagnostics, and Array Built in Self-Test (ABIST) repair techniques in accordance with preferred embodiments

FIGS. 3, and 4 respectively illustrate example operational steps for implementing integrated circuit yield enhancement through array fault detection and correction using combined Logic Built in Self Test (LBIST) diagnostics, and Array Built in Self-Test (ABIST) repair techniques in accordance with preferred embodiments of the invention;

FIG. 5 is a block diagram illustrating a computer program product in accordance with the preferred embodiment; and

FIG. 6 is a flow diagram of a design process used in semiconductor design, manufacturing, and/or test.

### DETAILED DESCRIPTION OF THE PREFERRED EMBODIMENTS

In the following detailed description of embodiments of the invention, reference is made to the accompanying drawings, which illustrate example embodiments by which the invention may be practiced. It is to be understood that other embodiments may be utilized and structural changes may be made without departing from the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In accordance with features of the invention, methods and circuit are provided for implementing integrated circuit yield enhancement through array fault detection and correction using combined Logic Built in Self Test (LBIST) diagnostics, and Array Built in Self-Test (ABIST) repair techniques, and a design structure on which the subject circuit resides. A combined operation of LBIST and ABIST logic is used to identify and repair failures in the random logic feeding to and from array and array cell fails. The combination of running LBIST along with the arrays while also implementing a method of recording the array related LBIST fails for inclusion into a repair algorithm using redundant array structures enables integrated circuit yield enhancement.

A conventional combined LBIST approach as it currently exists, only identifies, a chip as passing or failing a given test. This is typical of any sort of LBIST, and most other, manufacturing tests. For the purpose of sorting passing and failing devices this suffices for random logic. However, memory arrays need to be treated differently. Due to the dense amount of array content on most state of the art devices, and their relatively low yield, additional testing methods are employed. A robust implementation of ABIST may include a repair strategy where redundant structures on the chip are used to swap in good bits for the failing bits, allowing for increased manufacturing yield. ABIST identifies array cells (address and bit) and allows for repair functions, but does not fully test the interface logic to the surrounding circuitry which can lead to faulty array operation. The present invention uses a combined, simultaneous LBIST and ABIST operation to identify and potentially repair both the random logic feeding to and from the array and array cell fails. Currently the practice is to scrap all combined LBIST failing devices.

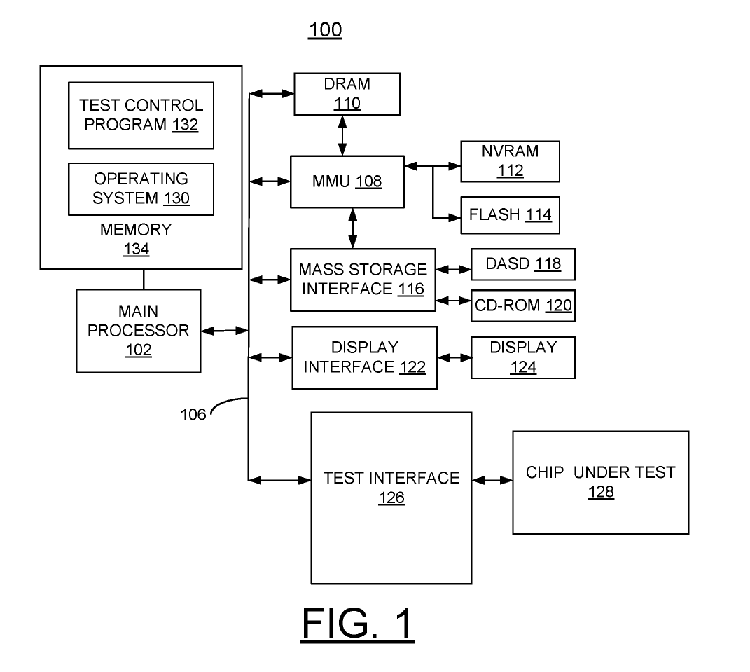

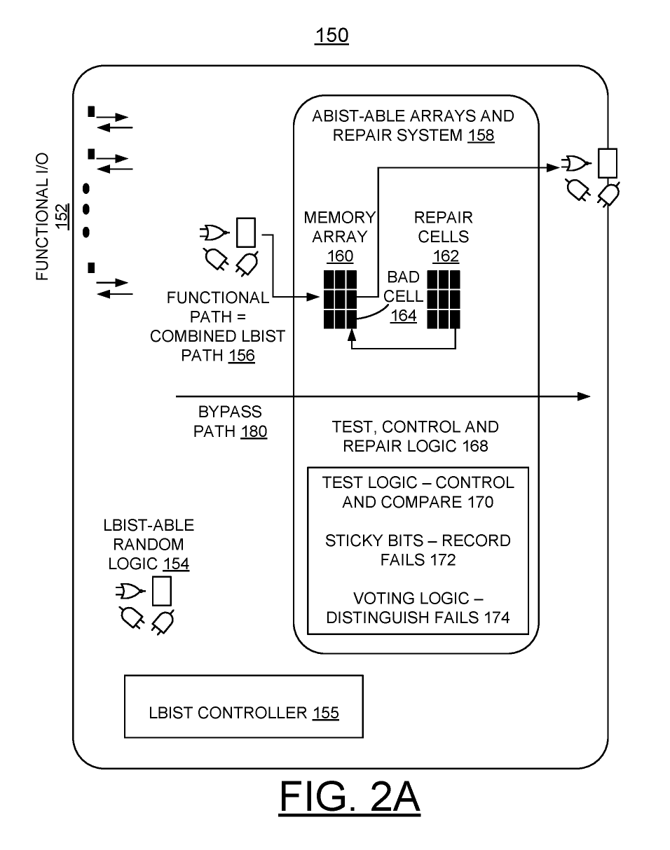

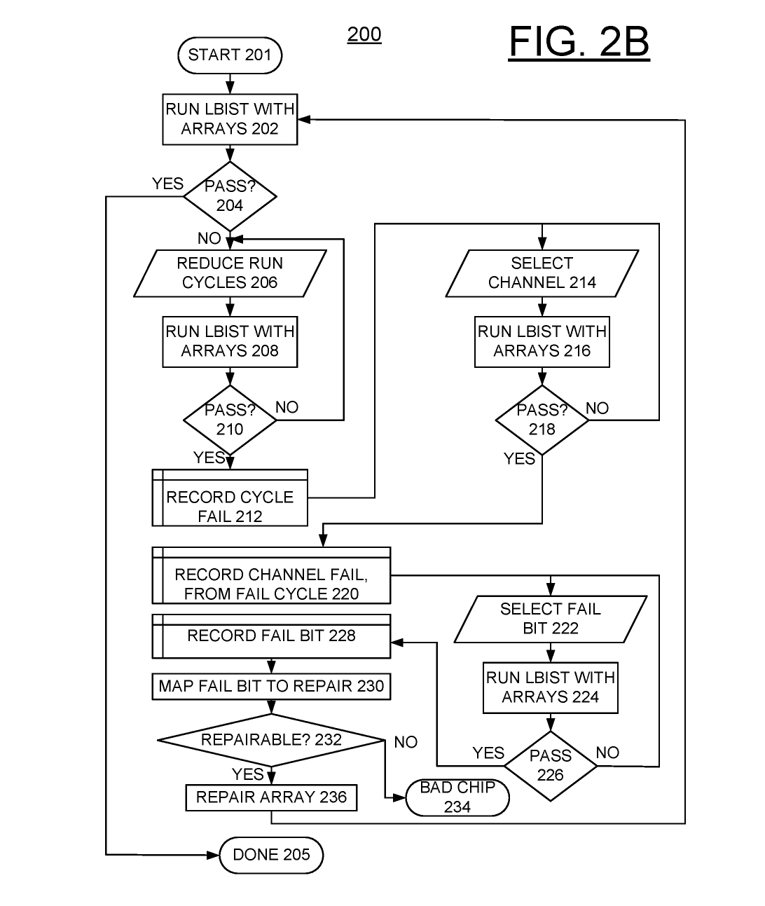

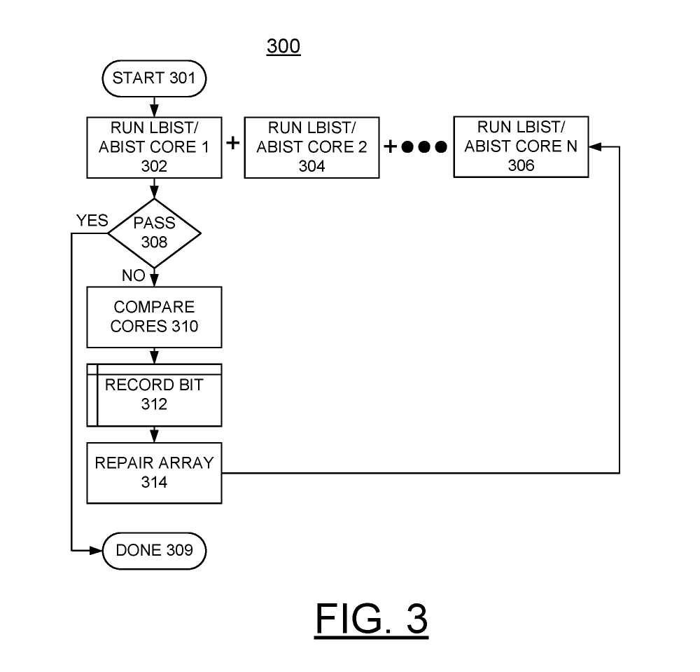

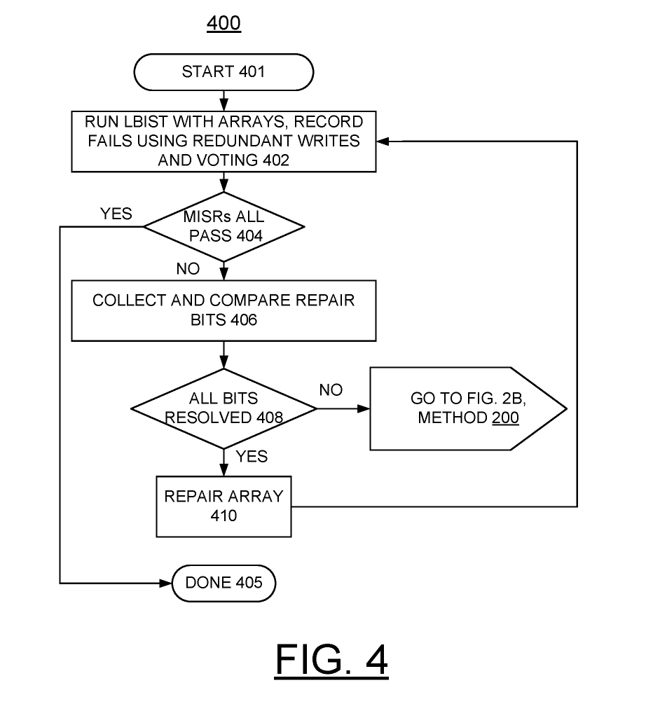

Having reference now to the drawings, in FIGS. 1, and 2A, there is shown an exemplary computer test system for implementing integrated circuit yield enhancement through array fault detection and correction using combined Array Built in Self-Test (ABIST) and Logic Built in Self Test (LBIST) diagnostics, and repair techniques generally designated by the reference character 100 in accordance with the preferred embodiment. Computer system 100 includes a main processor 102 or central processor unit (CPU) 102 coupled by a system bus 106 to a memory management unit (MMU) 108 and system memory including a dynamic random access memory (DRAM) 110, a nonvolatile random access memory (NVRAM) 112, and a flash memory 114. A mass storage interface 116 coupled to the system bus 106 and MMU 108 connects a direct access storage device (DASD) 118 and a CD-ROM drive 120 to the main processor 102. Computer system 100 includes a display interface 122 connected to a display 124, and a test interface 126 coupled to the system bus 106. An integrated circuit device or chip under test 128 is coupled to the test interface 126. Computer system 100 includes an operating system 130, and a test control program 132 of the preferred embodiment resident in a memory 134. The test interface 126 provides selective control by the test control program 132 for example operations as illustrated and described with respect to FIGS. 2B, 3 and 4.

Computer test system 100 includes a circuit 150, FIG. 2A, with functional Input/Output (I/O) 152, LBIST-able random logic 154, and a functional path or combined LBIST path 156 extending through an ABIST-able arrays and repair system 158. ABIST-able arrays and repair system 158 includes memory array 160, repair cells 162, with a bad cell 164. ABIST-able arrays and repair system 158 includes test, control, and repair logic 168. The test, control, and repair logic 168 includes test logic for control and compare 170, sticky bits to record fails 172, and voting logic to distinguish fails 174. Circuit 150 includes a bypass path 180 extending through the ABIST-able arrays and repair system 158.

Computer test system 100 is shown in simplified form sufficient for understanding the present invention. The illustrated computer test system 100 is not intended to imply architectural or functional limitations. The present invention can be used with various hardware implementations and systems and various other internal hardware devices, for example, multiple main processors.

In accordance with features of the invention, an automated method significantly cuts out manual intervention and diagnostics for any per chip testing. This is accomplished using a combination of LBIST 155, ABIST 158, and Repair logic 168 capabilities with minimal additional logic and algorithm development. In the case of robust BIST and Repair implementations a representative example is demonstrated utilizing on chip diagnostics, resulting in minimized manual intervention. LBIST 155 is run on both random and array logic 158 by defeating any write-through or bypass logic within the arrays, and clocking the arrays while under the LBIST test operation using function combined LBIST path 156. With the arrays participating in this Combined LBIST mode and utilizing the existing ABIST logic 170, the sticky bits 172 normally used for recording ABIST only operation fails are re-tasked to record combined LBIST array fail locations. At the end of a combined LBIST run any array cell fails are already encoded on-chip. Having the failing cell locations 172 recorded on-chip or circuit 150, the known algorithm advantageously is used, to directly map the fail locations into a repair solution identically to the existing redundant cell to failing bit correlation used for ABIST repair.

In accordance with features of the invention, a key feature is to record and use the failing cell data on-chip to provide a repair solution, thus recovering otherwise lost yield. There are multiple tradeoffs and different implementations that can be developed to accomplish this goal. The sticky bits 172 are a natural choice for efficient use of existing on-chip repair logic but may require additional logic in the form of either a voting structure 174 or side register additions. Options for hardware enablement include, but are not limited to: 1) Modify the write so that the location being written gets at least 3 copies (4 is likely easiest) of the same data in separate portions of the data word, then when the read occurs a comparison of data portions will point to the failing location via sticky bit saving. 2) Creating a function that always writes to at least 3 locations for every write (4 is likely easiest), then when a read occurs, only the same portion of each word is read and compared with fails saved in sticky bits. The portion selected can randomly rotate to cover all locations of all words.

In accordance with features of the invention, each of these hardware based solutions covers some, but not all of the functional array usage paths, adds logic and timing paths that may affect design performance and may require extra clocking for sticky bit recording, and maybe extra reading of sticky bits after the test, so are not preferred to the common core comparison or post-analysis solutions. LBIST is a pseudo random operation where the logical value written to the arrays would be cumbersome to determine and store prior to runtime (prediction). Thus an automated method needs to self-determine the correct value with some acceptable certainty. This is where additional voting logic 174 or sideband registers can be implemented. A multiple write operation where the same data is written to several locations and a comparison (voting) is performed advantageously is implemented on existing hardware with minimal change. A voting scheme to determine the failing cells is implemented by either writing multiple cells, or multiple arrays, with the same data and a small logic addition to compare results and determine the dissenting bit. A redundant (test only) location could be added and written for comparison with a moderate amount of additional logic. This method could perform complete bit recording for test comparison only, although while giving a 100% comparison, it costs significant additional logic over the voting method.

Referring to FIGS. 2B, there are shown example operational steps generally designated by the reference character 200 for implementing integrated circuit yield enhancement through array fault detection and correction using combined Logic Built in Self Test (LBIST) diagnostics, and Array Built in Self-Test (ABIST) repair techniques starting at block 201 in accordance with preferred embodiments. Method 200 provides similar logic direct mapping in accordance with preferred embodiments, though without forcing data or using sticky bit immediate recording, minimizing additional logic.

As indicated at block 202, running combined LBIST or LBIST with arrays is performed. Checking is performed for passing test data, as indicated at decision block 204. When passing data is identified, then the operations are completed as indicated at block 205. When a fail is identified, then the number of cycles is reduced as indicated at block 206. As indicated at block 208, running combined LBIST or LBIST with arrays is performed. Checking is performed for passing test data, as indicated at decision block 210. When passing data is identified, then the previously found cycle fail is recorded as indicated at block 212.

In accordance with features of the invention, to diagnose failing data, full test is reduced to first single failing cycle of implicated MISR. MISR cycle data is reduced to single failing channel. Then channel is reduced to single failing bit information.

When a fail is identified, then a channel to block is selected as indicated at block 214. As indicated at block 216, running LBIST with arrays is performed. Checking is performed for passing test data, as indicated at decision block 218. When a pass is not identified, then another channel to block is selected as indicated at block 214. When passing data is identified, then channel fail is recorded from fail cycle as indicated at block 220. As indicated at block 222, a fail bit to block is selected. As indicated at block 224, running LBIST with arrays is performed. Checking is performed for passing test data, as indicated at decision block 226. When passing data is identified, then the fail bit is recorded as indicated at block 228.

In accordance with features of the invention, mapping failing bit data into repair register is performed, which is a unique use of fail data to repair array cell. Failing bit can be mapped to failing address repair register (FARR). Failing bit is now known, and can be mapped to redundant cell using offline tables and manual intervention. Once the data is mapped, the repair information becomes a resident part of array repair.

In accordance with features of the invention, since LBIST is pseudo-random, some locations that are written may never have been read by the time LBIST is complete. An additional dump of array data and comparison of expected results could show additional write miscompares that then could be included in the repair. This additional step is true for all the various methods described here. While the method 200 of FIG. 2B relies on tester debug time, other advantageous methods 300 and 400 would directly compare, say in the case of multiple core logic as illustrated and described with respect to FIG. 3, and FIG. 4, a passing region directly to a failing region to immediately identify the implicated array cell locations. These methods 300 and 400 would reduce diagnostic time and provide the same fail mapping as method 200 of FIG. 2B which can then be used to direct redundant cell replacement for repair.

As indicated at block 230, the fail bit is mapped to repair. Checking if the fail is repairable is performed at a decision block 232. If not repairable, the chip is marked as bad at a block 234. If repairable, the array is repaired at a block 236. Then the operations return to block 202 to run LBIST with arrays to assure repair is correct and complete. Array repair is performed with updated repair information, and combined LBIST is re-run.

Referring to FIGS. 3, and 4, there are shown example operational steps respectively generally designated by the reference characters 300, 400 for implementing integrated circuit yield enhancement through array fault detection and correction using combined Logic Built in Self Test (LBIST) diagnostics, and Array Built in Self-Test (ABIST) repair techniques in accordance with preferred embodiments of the invention.

In FIG. 3, operations start at a block 301. As indicated at blocks 302, 304, 306, running combined LBIST and ABIST for core 1, core 2, through core N is performed. Checking for pass is performed as indicated at decision block 308. With all passing data, the operations are complete as indicated at block 309. Otherwise, the cores are compared as indicated at block 310. A routine is performed to record each fail bit as indicated at block 312. The array is repaired as indicated at block 314, and then the operations return to blocks 302, 304, and 306, running combined LBIST and ABIST for core 1, core 2, through core N.

In accordance with features of the invention, method 400 of FIG. 4 shows the simplified algorithm used when self diagnostic features have been added to hardware. Note, that in the event the self diagnostic routine fails to resolve all array and repair bits a manual method (such as method 200 of FIG. 2B) can still be used for further fail isolation.

In FIG. 4, operations start at a block 401. As indicated at block 402 run LBIST with arrays, record fails using redundant writes, and voting is performed. At block 402, the chip produces MISR data and self-records failing array cell data. Checking whether all MISRs pass is performed at a decision block 404. Failing data is diagnosed based on MISR pass and fail results, where all passing MISRs, no action required as indicated at a block 405. One or more failing MISRs indicate analysis and possible repair are needed. Repair bits are collected and compared as indicated at block 406. Checking for all bits resolved is performed at a decision block 408. Automated or manual repair may be required when the voting method fails, going to method 200 of FIG. 2B. When all bits are resolved, the array is repaired as indicated at block 410. Then combined LBIST is re-run returning to block 402 to assure repair is correct and complete.

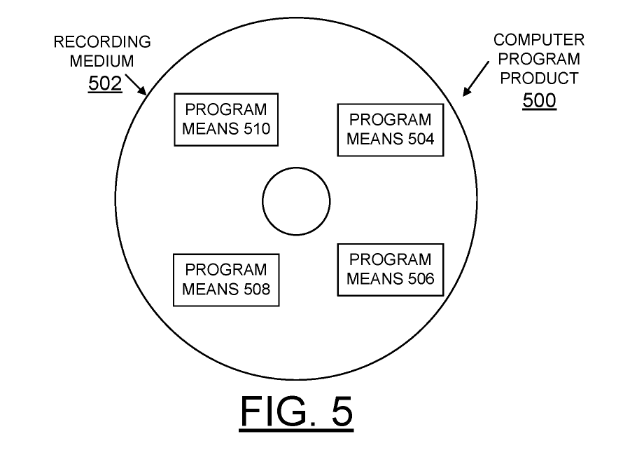

Referring now to FIG. 5, an article of manufacture or a computer program product 500 of the invention is illustrated. The computer program product 500 includes a recording medium 502, such as, a floppy disk, a high capacity read only memory in the form of an optically read compact disk or CD-ROM, a tape, or another similar computer program product. Recording medium 502 stores program means 504, 506, 508, 510 on the medium 502 for carrying out the methods for implementing combined Logic Built in Self Test (LBIST) diagnostics, and Array Built in Self-Test (ABIST) repair techniques s of the preferred embodiment in the system 100 of FIGS. 1, and 2A.

A sequence of program instructions or a logical assembly of one or more interrelated modules defined by the recorded program means 504, 506, 508, 510, direct the computer system 200 for implementing combined Logic Built in Self Test (LBIST) diagnostics, and Array Built in Self-Test (ABIST) repair techniques of the preferred embodiment.

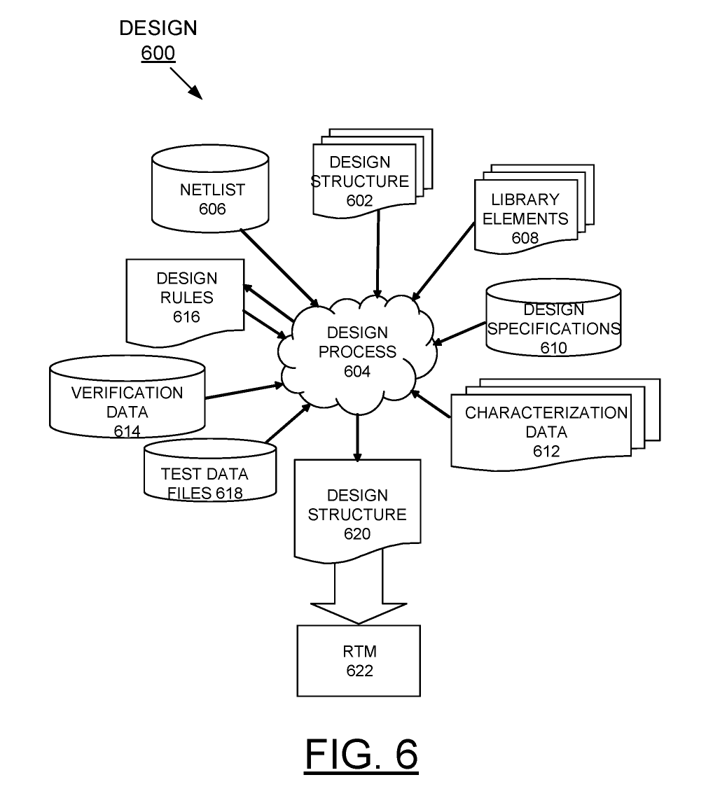

FIG. 6 shows a block diagram of an example design flow 600. Design flow 600 may vary depending on the type of IC being designed. For example, a design flow 600 for building an application specific IC (ASIC) may differ from a design flow 600 for designing a standard component. Design structure 602 is preferably an input to a design process 604 and may come from an IP provider, a core developer, or other design company or may be generated by the operator of the design flow, or from other sources. Design structure 602 comprises circuit 150 in the form of schematics or HDL, a hardware-description language, for example, Verilog, VHDL, C, and the like. Design structure 602 may be contained on one or more machine readable medium. For example, design structure 602 may be a text file or a graphical representation of circuit 150. Design process 604 preferably synthesizes, or translates, circuit 150 into a netlist 606, where netlist 606 is, for example, a list of wires, transistors, logic gates, control circuits, I/O, models, etc. that describes the connections to other elements and circuits in an integrated circuit design and recorded on at least one of machine readable medium. This may be an iterative process in which netlist 606 is resynthesized one or more times depending on design specifications and parameters for the circuits.

Design process 604 may include using a variety of inputs; for example, inputs from library elements 608 which may house a set of commonly used elements, circuits, and devices, including models, layouts, and symbolic representations, for a given manufacturing technology, such as different technology nodes, 32 nm, 45 nm, 90 nm, and the like, design specifications 610, characterization data 612, verification data 614, design rules 616, and test data files 618, which may include test patterns and other testing information. Design process 604 may further include, for example, standard circuit design processes such as timing analysis, verification, design rule checking, place and route operations, and the like. One of ordinary skill in the art of integrated circuit design can appreciate the extent of possible electronic design automation tools and applications used in design process 604 without deviating from the scope and spirit of the invention. The design structure of the invention is not limited to any specific design flow.

Design process 604 preferably translates an embodiment of the invention as shown in FIG. 2A along with any additional integrated circuit design or data (if applicable), into a second design structure 620. Design structure 620 resides on a storage medium in a data format used for the exchange of layout data of integrated circuits, for example, information stored in a GDSII (GDS2), GL1, OASIS, or any other suitable format for storing such design structures. Design structure 620 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 2A. Design structure 620 may then proceed to a stage 622 where, for example, design structure 620 proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

What is claimed is:

1. A method for implementing integrated circuit yield enhancement through array fault detection and correction using combined Logic Built in Self Test (LBIST) diagnostics and Array Built in Self-Test (ABIST) repair techniques comprising:
using combined operation of LBIST and ABIST logic and identifying failures in the random logic feeding to and from the arrays and array cell failures;
recording identified failures for inclusion into a repair algorithm; and
using redundant structures for repair of said identified failures to enable integrated circuit yield enhancement.

2. The method as recited in claim 1 wherein using combined operation of LBIST and ABIST logic and identifying failures in the random logic feeding to and from the arrays and array cell failures includes running combined LBIST and arrays tests and checking for passing test data.

3. The method as recited in claim 1 includes identifying unique array failures in both an array and interface logic feeding to and from the array.

4. The method as recited in claim 2 includes running multiple combined LBIST and arrays tests to find failing locations.

5. The method as recited in claim 1 wherein using combined operation of LBIST and ABIST logic and identifying failures includes running combined LBIST and repair algorithm after a device under test is incorporation into a system.

6. The method as recited in claim 5 includes running combined LBIST and repair algorithm after the system is delivered to a user.

7. The method as recited in claim 1 wherein using combined operation of LBIST and ABIST logic and identifying failures in the random logic feeding to and from the arrays and array cell failures includes noting and recording Multiple Input Signature Register (MISR) data.

8. The method as recited in claim 7 includes to diagnose failing data, reducing a full test to a first single failing cycle of an MISR, reducing MISR cycle data to single failing channel, and reducing the channel to single failing bit information.

9. The method as recited in claim 1 includes mapping failing bit data into a repair register with unique use of fail data to repair array cell.

10. The method as recited in claim 1 includes mapping failing bit data into a failing address repair register (FARR), said mapped failing bit data becomes a part of array repair.

11. The method as recited in claim 1 includes running combined LBIST and arrays tests for each of multiple cores and directly comparing a passing region directly to a failing region to identify failed array cell locations.

12. The method as recited in claim 1 includes running combined LBIST and arrays tests and diagnosing failing data based on Multiple Input Signature Register (MISR) data pass and fail results.

13. The method as recited in claim 1 wherein recording identified failures for inclusion into a repair algorithm includes using sticky bit data recorded on-chip.

14. The method as recited in claim 1 wherein recording identified failures for inclusion into a repair algorithm includes using voting logic to distinguish failures.

15. A computer test system and circuit for implementing integrated circuit yield enhancement through array fault detection and correction using combined Logic Built in Self Test (LBIST) diagnostics and Array Built in Self-Test (ABIST) repair techniques comprising:
a processor;
a test control program, said processor using said test control program for performing the steps of:
running combined operation of LBIST and ABIST diagnostics and identifying failures in random logic feeding to and from the arrays and array cell failures;
recording identified failures for inclusion into a repair algorithm; and
using redundant array structures for repair of at least one of said identified failures for enabling integrated circuit yield enhancement.

16. The computer test system and circuit as recited in claim 15 includes voting logic to distinguish failures for recording identified failures for inclusion into a repair algorithm.

11. The computer test system and circuit as recited in claim 15 includes a failing address repair register (FARR) for storing mapped failing bit data, said mapped failing bit data becomes a part of array repair.

18. The computer test system and circuit as recited in claim 15 includes said processor using said test control program for mapping failing bit data into a repair register with unique use of fail data to repair array cell.

19. The computer test system and circuit as recited in claim 18 includes noting and recording Multiple Input Signature Register (MISR) data.

20. The computer test system and circuit as recited in claim 18 includes diagnosing failing data is based on MISR pass and fail results.
